(19) United States
(12) Patent Application Publication
(10) Pub. No.: US 2012/0056191 A1
(43) Pub. Date: Mar. 8, 2012

(54) SEMICONDUCTOR DEVICE, METHOD OF MANUFACTURING THE SAME, AND POWER SUPPLY APPARATUS

(75) Inventors: Hiroshi Endo, Kawasaki (JP); Tadahiro Imada, Kawasaki (JP); Kenji Imanishi, Kawasaki (JP); Toshihide Kikkawa, Kawasaki (JP)

(73) Assignee: FUJITSU LIMITED, Kawasaki (JP)

(21) Appl. No.: 13/152,426

(22) Filed: Jun. 3, 2011

(30) Foreign Application Priority Data
Sep. 2, 2010 (JP) 2010-197063

(51) Int. Cl. H01L 29/778; H01L 21/20

(52) U.S. Cl. 257/76; 438/478; 257/194; 257/E29.246; 257/E21.09

(57) ABSTRACT

A semiconductor device includes a GaN electron transport layer provided over a substrate; a first AlGaN electron supply layer provided over the GaN electron transport layer; an AlN electron supply layer provided over the first AlGaN electron supply layer; a second AlGaN electron supply layer provided over the AlN electron supply layer; a gate recess provided in the second AlGaN electron supply layer and the AlN electron supply layer; and a gate electrode provided over the gate recess.

### CROSS-REFERENCE TO RELATED APPLICATION

This application is based upon and claims the benefit of priority of the prior Japanese Patent Application No. 2010-197063, filed on Sep. 2, 2010, the entire contents of which are incorporated herein by reference.

### FIELD

The embodiment discussed herein relates to a semiconductor device, a method of manufacturing the same, and a power supply apparatus.

### BACKGROUND

Nitride semiconductor devices have a high saturated electron velocity, a wide band gap, and the like. By making use of the above-mentioned features, high breakdown voltage/high output devices have been undergoing active development.

Examples of nitride semiconductor devices used in high breakdown voltage/high output devices are field effect transistors such as high electron mobility transistors (HEMTs).

For example, a GaN-HEMT has a HEMT structure in which an AlGaN electron supply layer is formed over a GaN electron transport layer. Piezoelectric polarization occurs in the GaN-HEMT as a result of strains in the AlGaN electron supply layer, caused by differences in the lattice constant between the AlGaN electron supply layer and the GaN electron transport layer. A high concentration two-dimensional electron gas is obtained by piezoelectric polarization and spontaneous polarization in the AlGaN electron supply layer. Thus, by using the GaN-HEMT, a high breakdown voltage/high output device may be realized.

Japanese Patent Application Laid-Open Publication No. 2008-98455 is an example of a related art document.

Most of the reports regarding nitride semiconductor devices (e.g., GaN-HEMTs) to date have been about devices that operate in the normally-on mode.

However, normally-off type transistors are preferred because current continues to flow, for example, in the event of a failure in normally-on type transistors.

A normally-off type transistor may be realized by setting the threshold voltage positive. To set the threshold voltage positive, it is preferred that a gate recess be provided and the depth of the gate recess be controlled precisely.

However, in a conventional nitride semiconductor device, a gate recess is formed by dry etching. It is difficult to control the depth of a gate recess because a suitable dry etching technology has not been established at present. Thus, since variations in the depth of the gate recesses occur and setting the threshold voltage positive is difficult, it has not been possible to steadily manufacture devices that operate in the normally-off mode.

### SUMMARY

According to an aspect of an embodiment, a semiconductor device includes a GaN electron transport layer provided over a substrate; a first AlGaN electron supply layer provided over the GaN electron transport layer; an AlN electron supply layer provided over the first AlGaN electron supply layer; a second AlGaN electron supply layer provided over the AlN electron supply layer; a gate recess provided in the second AlGaN electron supply layer and the AlN electron supply layer; and a gate electrode provided over the gate recess.

According to another aspect of an embodiment, a power supply apparatus includes a high-voltage circuit; a low-voltage circuit; and a transformer that is provided between the high-voltage circuit and the low-voltage circuit; the high-voltage circuit that includes a transistor, the transistor including a GaN electron transport layer provided over a substrate; a first AlGaN electron supply layer provided over the GaN electron transport layer; an AlN electron supply layer provided over the first AlGaN electron supply layer; a second AlGaN electron supply layer provided over the AlN electron supply layer; a gate recess provided in the second AlGaN electron supply layer and the AlN electron supply layer; and a gate electrode provided over the gate recess.

According to another aspect of an embodiment, a method of manufacturing a semiconductor device includes forming a GaN electron transport layer over a substrate; forming a first AlGaN electron supply layer over the GaN electron transport layer; forming an AlN electron supply layer over the first AlGaN electron supply layer; forming a second AlGaN electron supply layer over the AlN electron supply layer; forming a gate recess in the second AlGaN electron supply layer and the AlN electron supply layer; and forming a gate electrode over the gate recess.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a sectional view illustrating a structure of a semiconductor device according to an embodiment;

FIGS. 2A to 2N are sectional views illustrating a method of manufacturing a semiconductor device according to the embodiment;

FIG. 3 is a sectional view illustrating another example of the method of manufacturing a semiconductor device according to the embodiment;

FIG. 4 is a sectional view illustrating the method of manufacturing a semiconductor device;

FIG. 5 is a graph illustrating the etching rate of GaN, the etching rate of AlN, and the etching selectivity ratio between GaN and AlN;

FIGS. 6A to 6C are graphs illustrating the performance of a semiconductor device;

FIG. 7 is a diagram illustrating a power supply apparatus according to the embodiment; and

FIG. 8 is a sectional view illustrating a modified example of the semiconductor device.

### DESCRIPTION OF EMBODIMENT

A semiconductor device according to an embodiment is a compound semiconductor device, and is a high breakdown voltage/high output device using, for example, nitride semiconductor materials. The semiconductor device may also be referred to as “nitride semiconductor device.”

Also, the semiconductor device includes a field effect transistor, in which nitride semiconductor materials are used. The field effect transistor may also be referred to as “nitride semiconductor field effect transistor.”

The semiconductor device includes a GaN-HEMT, in which GaN-based semiconductor materials are used, and which operates in the normally-off mode. The GaN-HEMT may also be referred to as “GaN-based device” or “semiconductor element.”

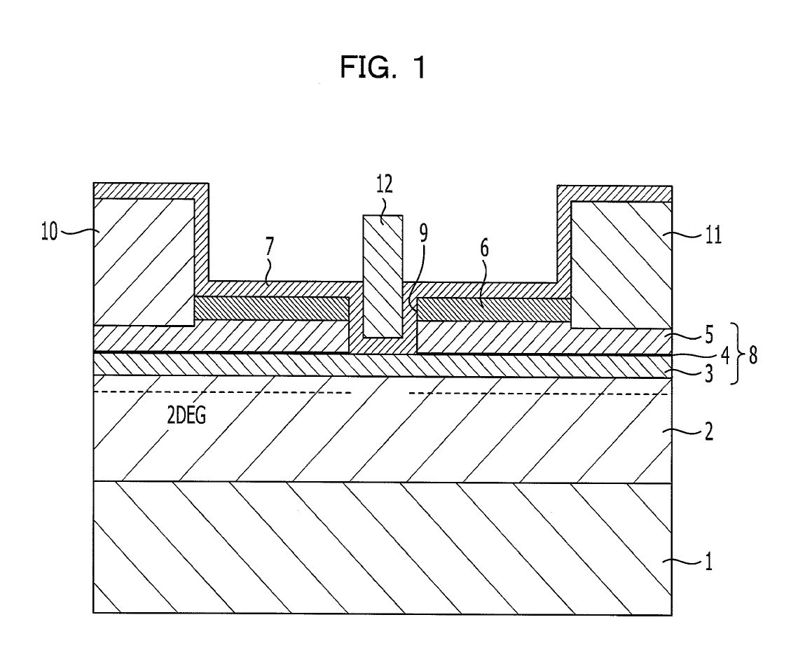

As illustrated in FIG. 1, the GaN-HEMT includes a GaN electron transport layer 2, a first AlGaN electron supply layer 3, an AlN electron supply layer 4, a second AlGaN electron supply layer 5, and a GaN protective layer 6 that are formed over a semi-insulating SIC substrate 1. The semiconductor stacked structure may also be referred to as “nitride semiconductor stacked structure” or “compound semiconductor stacked structure.”

An electron supply layer 8 includes the first AlGaN electron supply layer 3, the AlN electron supply layer 4, and the second AlGaN electron supply layer 5 in the GaN-HEMT. That is, the AlN electron supply layer 4 is provided between the first AlGaN electron supply layer 3 and the second AlGaN electron supply layer 5 in the GaN-HEMT. Thus, the electron supply layer 8 may be referred to as “AlGaN/AlN/AlGaN electron supply layer.” Due to the above-described structure, the depth of a gate recess 9 may be stably controlled with high precision as is mentioned below. That is, since the depth of the gate recess 9 may be controlled precisely and stably, it may be possible to steadily manufacture devices that operate in the normally-off mode.

In this embodiment, the first AlGaN electron supply layer 3 and the second AlGaN electron supply layer 5 are each, for example, an n-Al_{0.16}Ga_{0.84}N layer, and the thickness of the first AlGaN electron supply layer 3 and the second AlGaN electron supply layer 5 are each, for example, approximately 1 nm to approximately 100 nm. The first AlGaN electron supply layer 3 and the second AlGaN electron supply layer 5 are doped with, for example, Si as the n-type impurity at approximately 4×10¹⁸ cm⁻³. Although the first AlGaN electron supply layer 3 and the second AlGaN electron supply layer 5 are each the n-Al_{0.16}Ga_{0.84}N layer, the first AlGaN electron supply layer 3 may be an n-AlₓGa₁₋ₓN layer (0<x≦1), and the second AlGaN electron supply layer 5 may be an n-Al_{y}Ga_{1-y}N layer (0<y<1).

Although an Al content (Al composition) of the first AlGaN electron supply layer 3 and the second AlGaN electron supply layer 5 is substantially the same, the Al content (Al composition) is not limited thereto. As is mentioned below, when the gate recess 9 is formed, the second AlGaN electron supply layer 5 is selectively etched with respect to the AlN electron supply layer 4. The etching selectivity ratio in this case increases as the Al content of the second AlGaN electron supply layer 5 is reduced. That is, to ensure etching selectivity of the second AlGaN electron supply layer 5 with respect to the AlN electron supply layer 4, it is preferred that the Al content of the second AlGaN electron supply layer 5 be reduced. For example, it is preferred that the Al composition of the second AlGaN electron supply layer 5 be approximately 10% or less. Also, it is preferred that the Al content (Al composition) of the second AlGaN electron supply layer 5 be set so that the etching selectivity ratio with respect to the AlN electron supply layer 4 is approximately 10 or more. In this case, the second AlGaN electron supply layer 5 has a lower Al content than the first AlGaN electron supply layer 3. That is, the y value of a second Al_{y}Ga_{1-y}N electron supply layer 5 is smaller than the x value of a first AlₓGa₁₋ₓN electron supply layer 3.

The AlN electron supply layer 4 is, for example, an i-AlN layer, and the thickness of the AlN electron supply layer 4 is, for example, approximately 1 to approximately 3 nm. It is preferred that the thickness of the AlN electron supply layer 4 be approximately 3 nm or less. When the AlN electron supply layer 4 is thicker than approximately 3 nm, good crystallinity may not be obtained. Although in this embodiment, the AlN electron supply layer 4 is referred to as “i-AlN layer,” the AlN electron supply layer 4 is not limited thereto, but may be referred to as “n-AlN layer.” In this case, it is preferred that the AlN electron supply layer 4 be doped with, for example, Si as the n-type impurity at approximately 4×10¹⁸ cm⁻³.

A source electrode 10, a drain electrode 11, and a gate electrode 12 are provided over the semiconductor stacked structure.

That is, the source electrode 10 and the drain electrode 11 are provided over the second AlGaN electron supply layer 5 in the GaN-HEMT.

Also, the gate recess 9 is provided in the GaN protective layer 6, the second AlGaN electron supply layer 5, and the AlN electron supply layer 4, and the gate electrode 12 is provided over the gate recess 9.

In this embodiment, the surface of the semiconductor stacked structure is covered with an SiN film (insulating film) 7. The SiN film 7 extends from the surface of the GaN protective layer 6 and into the gate recess 9, and covers the bottom surface and the side surface of the gate recess 9 in addition to the surface of the GaN protective layer 6. That is, the surface of the GaN protective layer 6, which is exposed over the surface of the semiconductor stacked structure, is covered with the SiN film 7. Also, the surface of the first AlGaN electron supply layer 3, which is exposed over the bottom surface of the gate recess 9, is covered with the SiN film 7. Furthermore, the side surface of the GaN protective layer 6, the side surface of the second AlGaN electron supply layer 5, and the side surface of the AlN electron supply layer 4, which are exposed over the side surface of the gate recess 9, are covered with the SiN film 7.

The gate electrode 12 is provided over the first AlGaN electron supply layer 3 via the SiN film 7. That is, the SiN film 7 is provided inside the gate recess 9 and is provided between the gate electrode 12 and the first AlGaN electron supply layer 3, which is exposed over at least the bottom surface of the gate recess 9.

The SiN film 7 covering the surface of the semiconductor stacked structure may be a passivation film, and the SiN film 7 provided between the gate electrode 12 and the first AlGaN electron supply layer 3 serves as a gate insulating film.

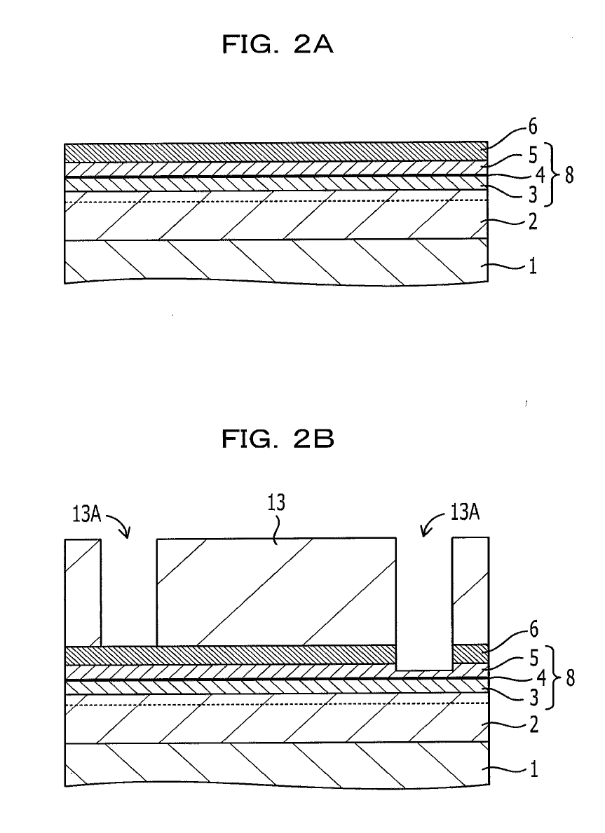

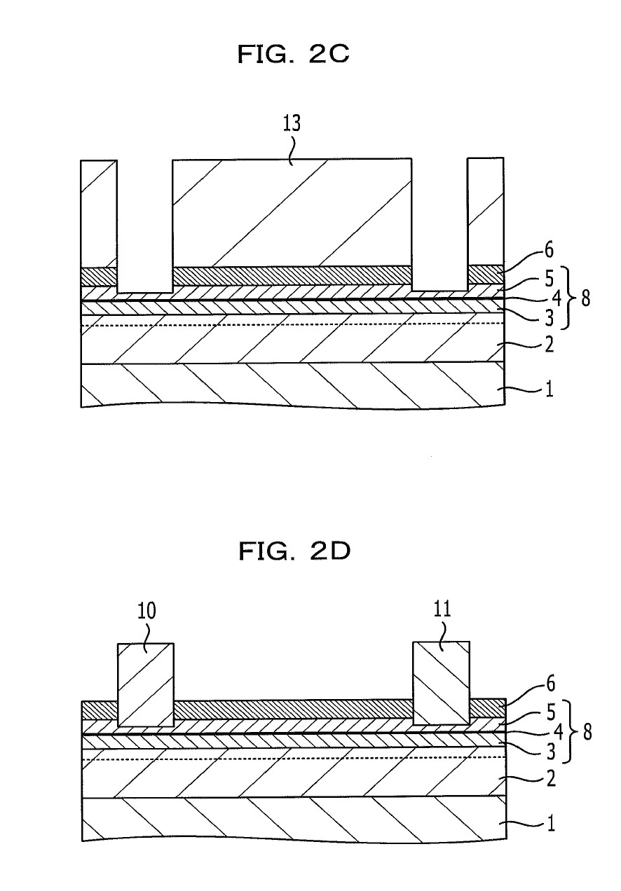

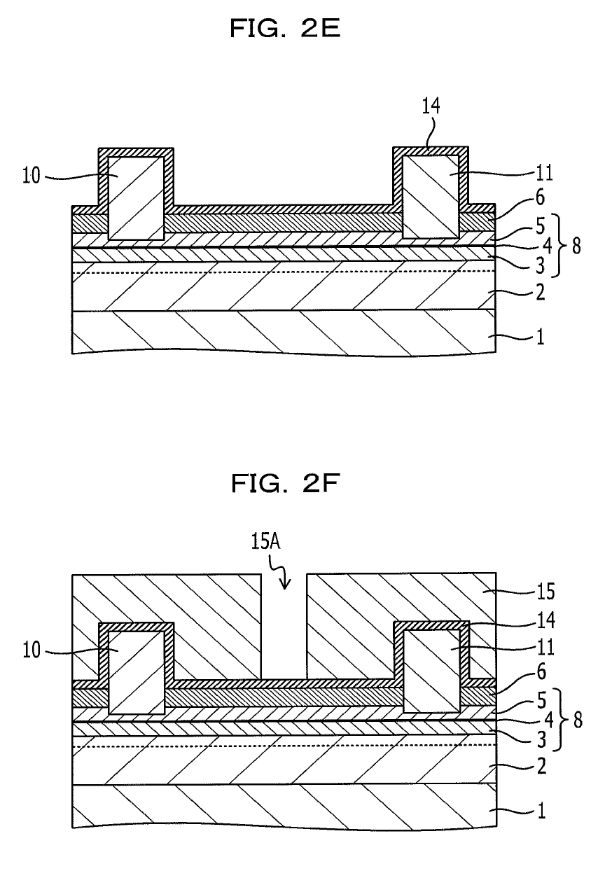

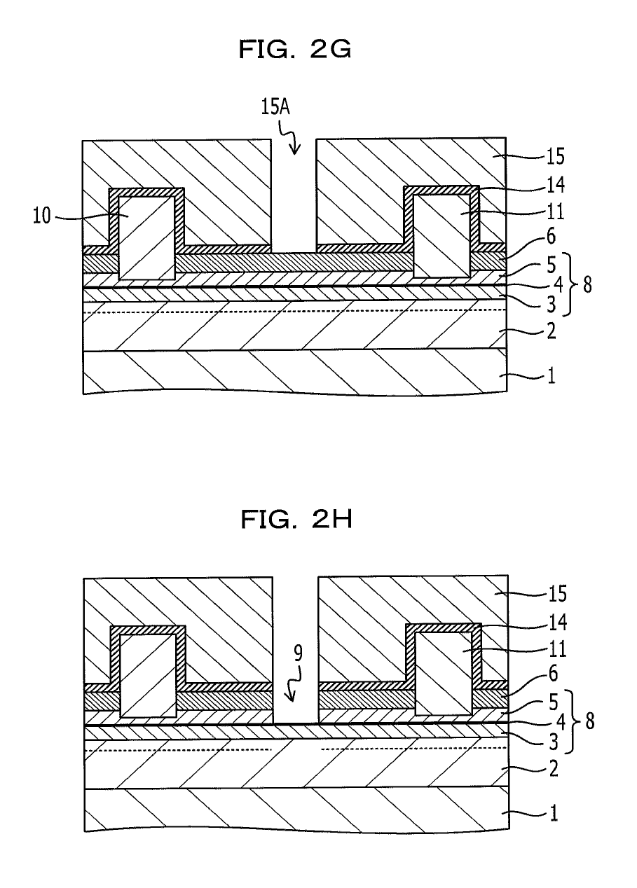

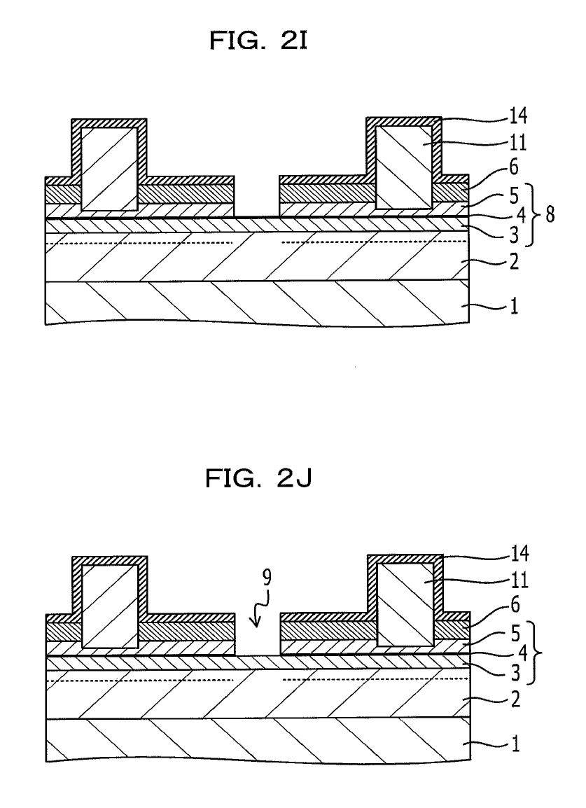

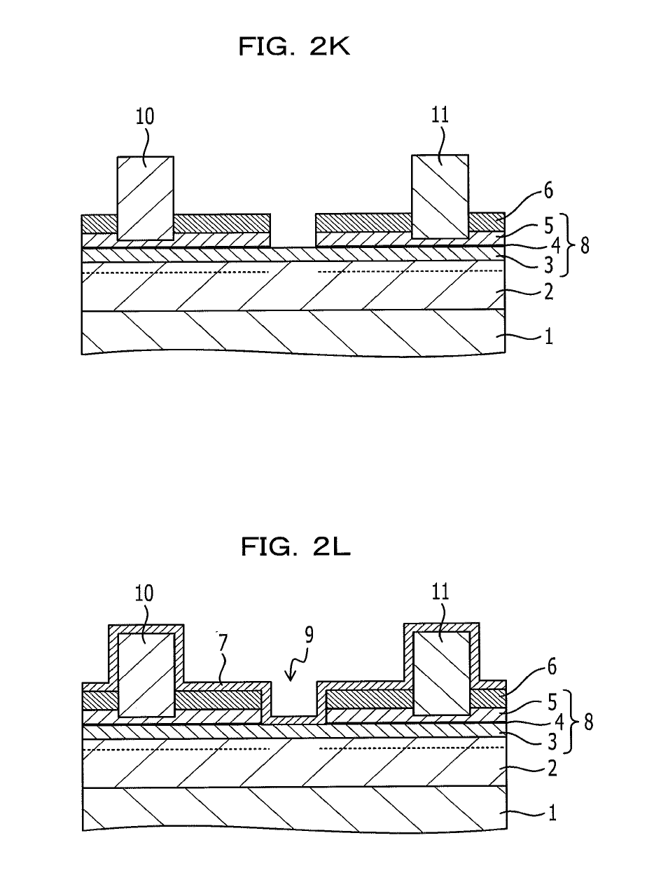

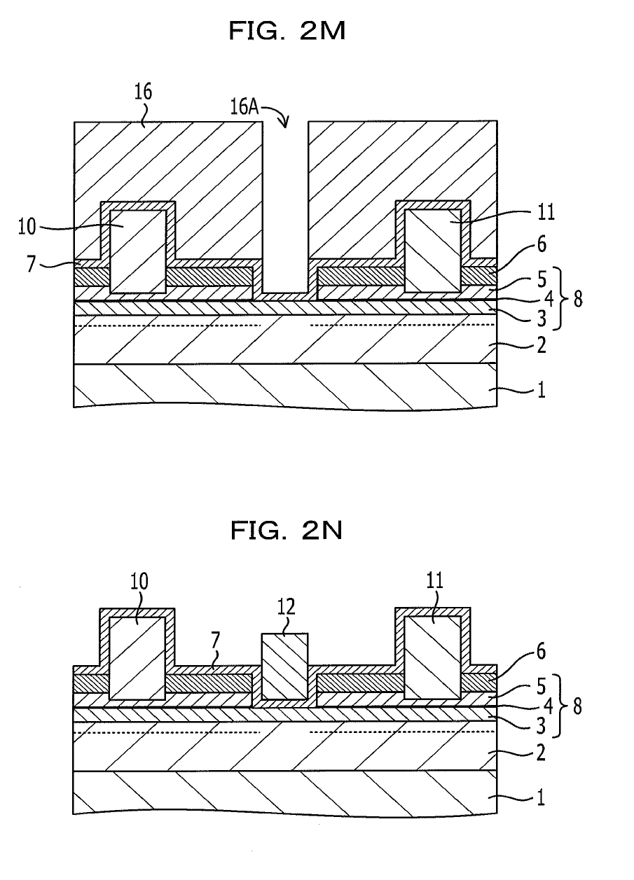

In FIGS. 2A to 2N, FIG. 3, and FIG. 4, a method of manufacturing a GaN-HEMT (semiconductor device) is illustrated.

As illustrated in FIG. 2A, an i-GaN electron transport layer 2, a first n-AlGaN electron supply layer 3, an i-AlN electron supply layer 4, a second n-AlGaN electron supply layer 5, and an n-GaN protective layer 6 are formed over a semi-insulating SiC substrate 1 by, for example, metal organic chemical vapor deposition (MOCVD).

That is, the i-GaN electron transport layer 2 is formed over the semi-insulating SiC substrate 1. The first n-AlGaN electron supply layer 3 is formed over the i-GaN electron transport layer 2. The i-AlN electron supply layer 4 is formed over the first n-AlGaN electron supply layer 3. The second n-AlGaN electron supply layer 5 is formed over the i-AlN electron supply layer 4. The n-GaN protective layer 6 is formed over the second n-AlGaN electron supply layer 5. Thus, a semiconductor stacked structure that includes an electron supply layer 8 including the first n-AlGaN electron supply layer 3, the i-AlN electron supply layer 4, and the second n-AlGaN electron supply layer 5, is formed.

The thickness of the i-GaN electron transport layer 2 is, for example, approximately 100 nm to approximately 1,000 nm.

Also, the first n-AlGaN electron supply layer 3 is, for example, an n-Al_{0.16}Ga_{0.84}N layer and the thickness of the first n-AlGaN electron supply layer 3 is, for example, approximately 1 nm to approximately 100 nm. For example, Si is used as the n-type impurity, and the doping concentration is, for example, approximately 4×10¹⁸ cm⁻³.

Also, the thickness of the i-AlN electron supply layer 4 is, for example, approximately 1 nm to approximately 3 nm. The i-AlN electron supply layer 4 may be doped with, for example, Si as the n-type impurity at approximately 4×10¹⁸ cm⁻³. Also, to obtain good crystallinity, it is preferred that the thickness of the i-AlN electron supply layer 4 be, for example, approximately 3 nm or less.

Also, the second n-AlGaN electron supply layer 5 is, for example, an n-Al_{0.16}Ga_{0.84}N layer and the thickness of the second n-AlGaN electron supply layer 5 is approximately 1 nm to approximately 100 nm. For example, Si is used as the n-type impurity, and the doping concentration is, for example, approximately 4×10¹⁸ cm⁻³.

As is mentioned below, when the gate recess 9 is formed, the second n-AlGaN electron supply layer 5 is selectively etched with respect to the i-AlN electron supply layer 4. The etching selectivity ratio in this case increases as the Al content of the second n-AlGaN electron supply layer 5 decreases. That is, to ensure etching selectivity of the second n-AlGaN electron supply layer 5 with respect to the i-AlN electron supply layer 4, it is preferred that the second n-AlGaN electron supply layer 5 be formed with a lower Al content than the first n-AlGaN electron supply layer 3. For example, it is preferred that the second n-AlGaN electron supply layer 5 be formed with an Al composition of approximately 10% or less.

Also, the thickness of the n-GaN protective layer 6 is, for example, approximately 1 nm to approximately 10 nm. For example, Si is used as the n-type impurity, and the doping concentration is, for example, approximately 5×10¹⁸ cm⁻³.

As illustrated in FIG. 2B, a resist mask 13 that includes a window 13A, which is slightly larger than a source electrode formation region or a drain electrode formation region is formed, using, for example, a photolithographic technique.

As illustrated in FIG. 2C, using the resist mask 13, the n-GaN, protective layer 6 and a part of the second n-AlGaN electron supply layer 5 in each of the source electrode formation region and the drain electrode formation region are removed, for example, by dry etching using a chlorine-based gas.

As illustrated in FIG. 2D, a source electrode 10 and a drain electrode 11 that includes, for example, Ti/Al, are formed over the second n-AlGaN electron supply layer 5 in the source electrode formation region and the drain electrode formation region using, for example, a vapor deposition and lift-off technique.

Ohmic characteristics are obtained by, for example, performing heat treatment at a temperature of approximately 400° C. to approximately 600° C.:

As illustrated in FIG. 2E, a silicon nitride film (SiN film) 14 is formed over the surface of the semiconductor stacked structure.

As illustrated in FIG. 2F, a resist mask 15 that includes a window 15A, which is slightly larger than a gate recess formation region is formed, using, for example, the photolithographic technique.

As illustrated in FIG. 2G, using the resist mask 15; the silicon nitride film 14 in the gate recess formation region is removed, for example, by dry etching using a fluorine-based gas. The etching conditions herein are SF₆ (=15 sccm), RF power (=50 W), and gas pressure (2 Pa).

As illustrated in FIG. 2H, using the resist mask 15, the n-GaN protective layer 6 and the second n-AlGaN electron supply layer 5 in the gate recess formation region are removed, for example, by dry etching using a chlorine-based gas and a fluorine-based gas.

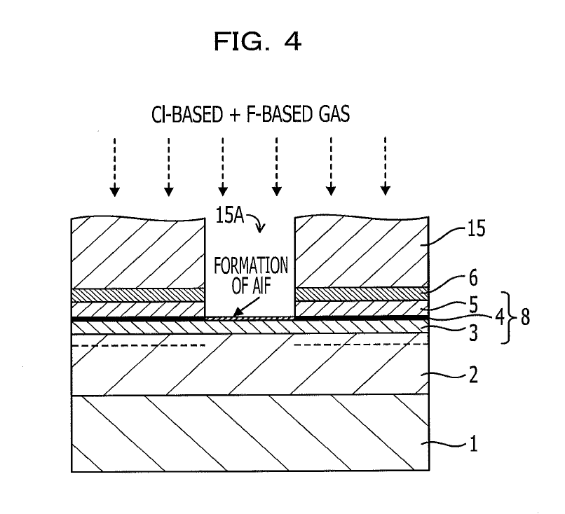

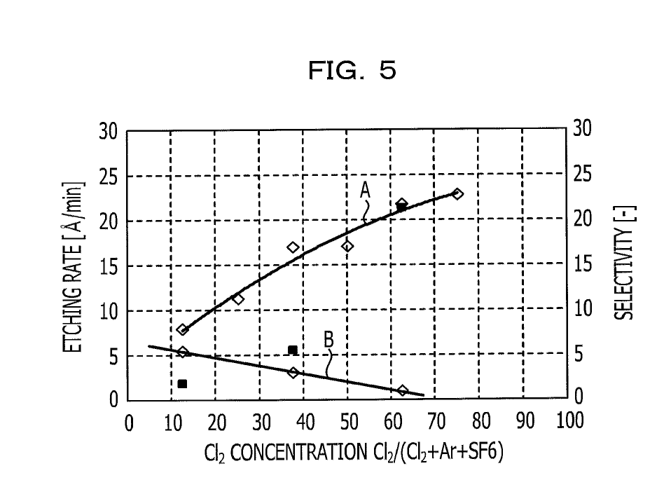

For example, by performing dry etching using a chlorine-based gas and a fluorine-based gas, the second n-AlGaN electron supply layer 5 is selectively removed with respect to the i-AlN electron supply layer 4. That is, for example, selective dry etching is performed using a chlorine-based gas and a fluorine-based gas, the second n-AlGaN electron supply layer 5 is removed, and the etching stops at the surface of the i-AlN electron supply layer 4. Thus, the i-AlN electron supply layer 4 may be an etching stop layer. This is because, as illustrated in FIG. 4, by using a fluorine-based gas as an etching gas, AlF is formed over the surface of the i-AlN electron supply layer 4 and etching the i-AlN electron supply layer 4 becomes difficult. The etching conditions herein are Cl₂/SF₆/Ar (=25/10/5 sccm), RF power (=20 W), and gas pressure (2 Pa). Etching selectivity between the second n-AlGaN electron supply layer 5 and the i-AlN electron supply layer 4 is ensured by performing dry etching under the above-mentioned conditions. Thus, the gate recess 9 is formed in the n-GaN protective layer 6 and the second n-AlGaN electron supply layer 5.

Although in this embodiment, the second n-AlGaN electron supply layer 5 is selectively removed with respect to the i-AlN electron supply layer 4 by performing dry etching using a chlorine-based gas and a fluorine-based gas, the method is not limited thereto. For example, the second n-AlGaN electron supply layer 5 may be selectively removed with respect to the i-AlN electron supply layer 4 by performing dry etching using a chlorine-based gas.

FIG. 5 is a graph illustrating the etching rate of GaN, the etching rate of AlN, and the etching selectivity ratio between GaN and AlN.

Cl₂/SF₆/Ar is used as an etching gas herein, and the total flow rate of Cl₂ and Ar is fixed at 30 sccm, the flow rate of SF₆ is fixed at 10 sccm, and the Cl₂ concentration of the etching gas [Cl₂/(Cl₂+SF₆+Ar)] is changed. Also, in FIG. 5, a solid line A represents changes in the etching rate of GaN, a solid line B represents changes in the etching rate of AlN, and the etching selectivity ratio is plotted in black squares.

As illustrated in FIG. 5, as the Cl₂ concentration in the etching gas increases, the etching rate of AlN decreases and the etching rate of GaN increases. Thus, as the Cl₂ concentration in the etching gas increases, the etching selectivity ratio of GaN to AlN increases. A large etching selectivity ratio of approximately 21.4 may be obtained by changing the Cl₂ concentration in the etching gas.

Although the etching rate of AlGaN may vary depending on the Al content, the etching rate and the etching selectivity ratio of GaN are discussed herein because the characteristics representing changes in the etching rate with respect to the Cl₂ concentration in the etching gas of AlGaN and GaN, are substantially the same. The characteristics representing changes in the etching rate of AlGaN descend in a direction in which the etching rate decreases (in a downward direction in FIG. 5) with respect to the characteristics representing changes in the etching rate of GaN (the solid line A). As the Al content of AlGaN increases, the characteristics representing changes in the etching rate of AlGaN descend further in the direction in which the etching rate decreases. As a result, as the Al content of AlGaN increases, the etching selectivity ratio decreases. Thus, the etching selectivity ratio obtained by changing the Cl₂ concentration in the etching gas changes with respect to the Al content (AI composition) of the second n-AlGaN electron supply layer 5. It is preferred that the Al content of the second n-AlGaN electron supply layer 5 be set so that the etching selectivity ratio with respect to the i-AlN electron supply layer 4 is, for example, approximately 10 or more.

As illustrated in FIG. 2I, the resist mask 15 is stripped off.

As illustrated in FIG. 2J, the i-AlN electron supply layer 4 in the gate recess formation region is removed, for example, by wet etching using phosphoric acid. When taking into account the etching rate and the like, it is preferred that the solution temperature of the phosphoric acid be approximately 80° C. For example, by performing wet etching using phosphoric acid, the i-AlN electron supply layer 4 is selectively removed with respect to the first n-AlGaN electron supply layer 3. That is, for example, selective wet etching is performed using phosphoric acid, the i-AlN electron supply layer 4 is removed, and the etching stops at the surface of the first n-AlGaN electron supply layer 3. Thus, the first n-AlGaN electron supply layer 3 may be the etching stop layer. Therefore, the gate recess 9 is formed in the i-AlN electron supply layer 4.

Although in this embodiment, phosphoric acid is used as an etchant (chemical solution), the etchant is not limited thereto, and for example, potassium hydroxide and tetra-methyl ammonium hydroxide (TMAH) may be used. In this case, when taking into account the etching rate and the like, it is preferred that the solution temperature be approximately 80° C.

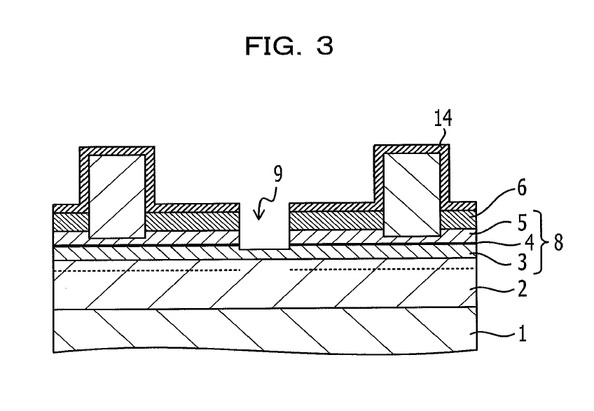

As illustrated in FIG. 3, for example, by using a resist mask formed by the photolithographic technique, a part of the first n-AlGaN electron supply layer 3 in the gate recess formation region may be removed, for example, by dry etching using a chlorine-based gas. In this case, dry etching may be time-controlled. The controllability of the depth of the gate recess is not affected since the etching amount is approximately 1 nm to approximately 2 nm.

As illustrated in FIG. 2K, the silicon nitride film 14 is removed, for example, by wet etching using hydrofluoric acid.

As illustrated in FIG. 2L, an SiN film (insulating film) 7 is formed over the surface of the semiconductor stacked structure. The SiN film 7 is formed so that the SiN film 7 extends from the surface of the n-GaN protective layer 6 and into the gate recess 9 and covers the bottom surface and the side surface of the gate recess 9 in addition to the surface of the n-GaN protective layer 6. The part of the SiN film 7 covering the surface of the n-GaN protective layer 6, which is the uppermost layer of the semiconductor stacked structure, serves as a passivation film. Also, the part of the SiN film 7 formed inside the gate recess 9, the part of the SiN film 7 formed over the first n-AlGaN electron supply layer 3, which is exposed over the bottom surface of the gate recess 9, serves as a gate insulating film.

As illustrated in FIG. 2M, a resist mask 16 that includes a window 16A in the gate electrode formation region is formed, using, for example, the photolithographic technique.

As illustrated in FIG. 2N, a gate electrode 12 that includes, for example, Ni/Au, is formed over the gate electrode formation region using, for example, the vapor deposition and lift-off technique. The gate electrode 12 is formed over the gate recess 9. That is, the gate electrode 12 is formed inside the gate recess 9 and is formed over the first n-AlGaN electron supply layer 3, which is exposed over the bottom surface of the gate recess 9 via the SiN film 7.

The wires of the source electrode 10, the drain electrode 11, the gate electrode 12, and the like are formed and the GaN-HEMT (semiconductor device) is completed.

Thus, the semiconductor device and the method of manufacturing the same in this embodiment are advantageous in that the depth of the gate recess 9 may be stably controlled and it may be possible to steadily manufacture devices that operate in the normally-off mode.

That is, according to this embodiment, the stability in the etching amount of the gate recess 9 may be ensured by forming the electron supply layer 8 so that the electron supply layer 8 includes the first n-AlGaN electron supply layer 3, the i-AlN electron supply layer 4, and the second n-AlGaN electron supply layer 5. Thus, the stability in the threshold voltage may be ensured, and the semiconductor device and the method of manufacturing the same in this embodiment are advantageous in that steadily manufacturing transistors that operate in the normally-off mode is made possible.

Also, by forming the electron supply layer 8 so that the electron supply layer 8 includes the i-AlN electron supply layer 4, which is provided between the first n-AlGaN electron supply layer 3 and the second n-AlGaN electron supply layer 5, a benefit of increasing the amount of two-dimensional electron gas may be obtained.

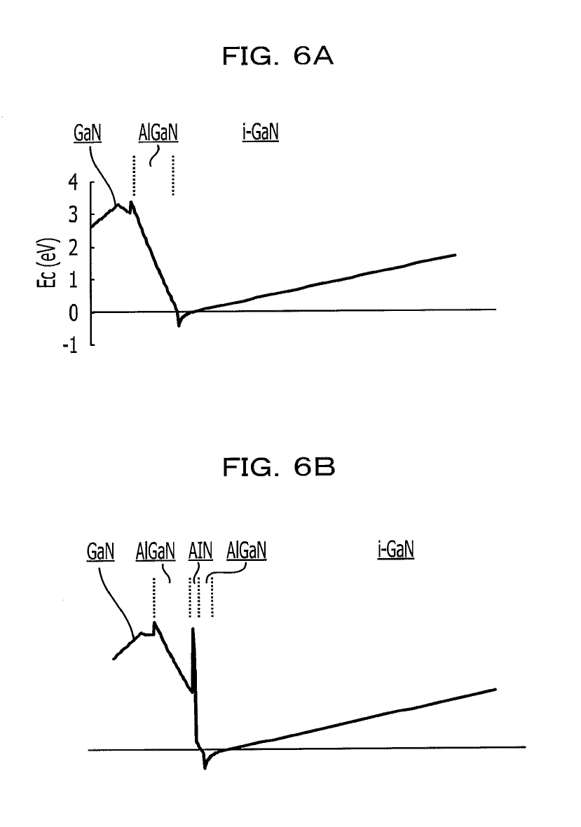

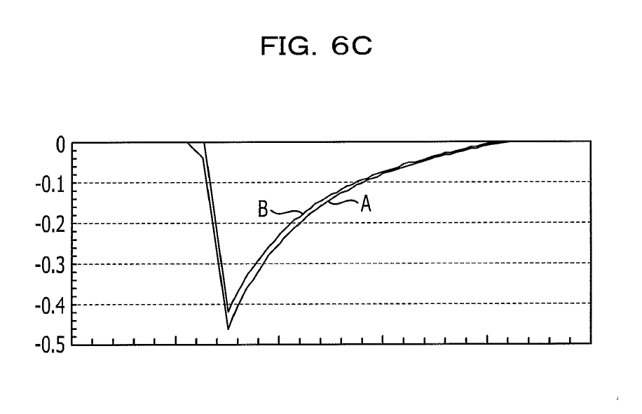

FIG. 6A illustrates a band structure of a conventional GaN-HEMT that does not include the i-AlN electron supply layer 4. Also, FIG. 6B illustrates a band structure of a GaN-HEMT that includes the i-AlN electron supply layer 4, which is provided between the first n-AlGaN electron supply layer 3 and the second n-AlGaN electron supply layer 5, according to this embodiment. In FIG. 6C, a part of the band structures are enlarged and illustrated. In FIG. 6C, the solid line A represents the band structure of the GaN-HEMT according to this embodiment and the solid line B represents the band structure of the conventional GaN-HEMT.

As illustrated in FIGS. 6A to 6C, since the i-AlN electron supply layer 4, which has a large band gap is provided between the first n-AlGaN electron supply layer 3 and the second n-AlGaN electron supply layer 5, the conduction band discontinuity between the electron supply layer 8 and the i-AlN electron supply layer 4 increases, as compared with when the i-AlN electron supply layer 4 is not provided. Thus, strong polarization occurs and the amount of two-dimensional electron gas increases.

As the amount of two-dimensional electron gas increases, as described above, the sheet resistance after crystal growth decreases and the on-resistance decreases, and as a result, high-frequency characteristics are improved.

The band structures, which are illustrated in FIGS. 6B and 6C, and benefits such as a reduction in the on-resistance may be obtained by, for example, setting the Al composition of the first n-AlₓGa₁₋ₓN electron supply layer 3 in the range of 0.15≦x≦1, and setting the Al composition of the second n-Al_{y}Ga_{1-y}N electron supply layer 5 in the range of 0.09≦y<1.

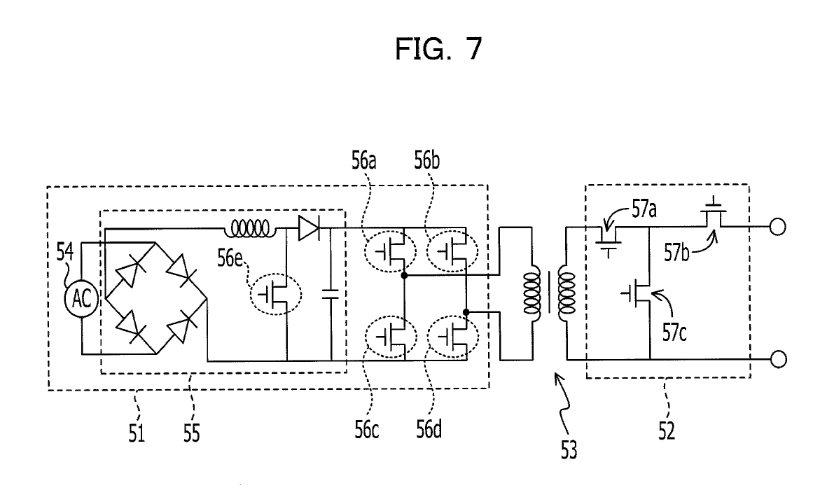

A power supply apparatus is described below with reference to FIG. 7.

A power supply apparatus according to this embodiment includes the above-described semiconductor device (GaN-HEMT).

As illustrated in FIG. 7, the power supply apparatus includes a high-voltage first circuit (high-voltage circuit) 51, a low-voltage second circuit (low-voltage circuit) 52, and a transformer 53 that is provided between the high-voltage first circuit 51 and the low-voltage second circuit 52.

The high-voltage first circuit 51 includes an alternating current (AC) source 54, a bridge rectifier circuit 55, and a plurality of switching elements such as a switching element 56a, a switching element 56b, a switching element 56c, and a switching element 56d. Also, the bridge rectifier circuit 55 includes a switching element 56e.

The low-voltage second circuit 52 includes a plurality of switching elements such as a switching element 57a, a switching element 57b, and a switching element 57c.

In this embodiment, the switching elements 56a, 56b, 56c, 56d, and 56e in the high-voltage first circuit 51 are the above-described GaN-HEMTs. The switching elements 57a, 57b, and 57c in the low-voltage second circuit 52 are MIS-FETs that include silicon.

Thus, the power supply apparatus according to this embodiment is advantageous in that a high output power supply apparatus may be realized since the high-voltage circuit includes the above-mentioned semiconductor devices (GaN-HEMTs). The normally-off operation may be stably realized, the on-resistance may be reduced, and high-frequency characteristics may be improved since the power supply apparatus includes the above-mentioned semiconductor devices (GaN-HEMTs).

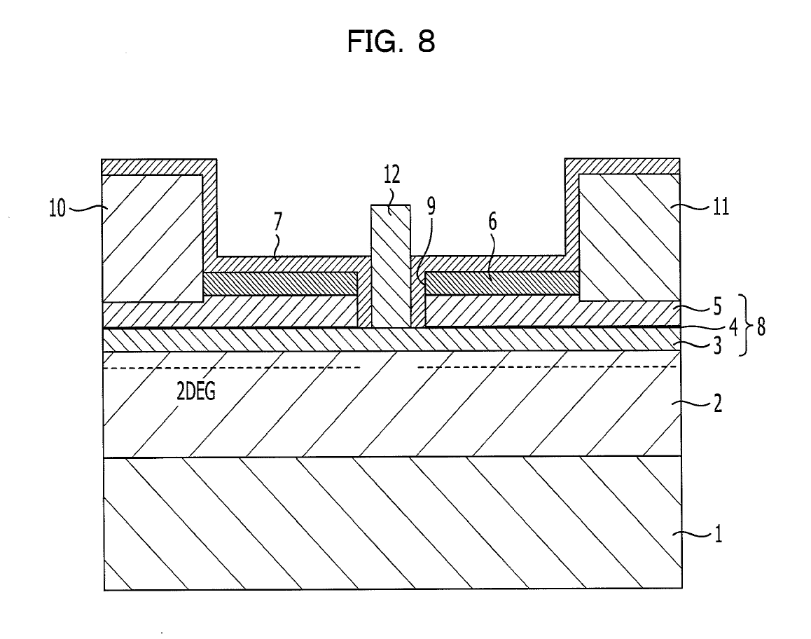

Although in the above-mentioned semiconductor device (GaN-HEMT), the gate electrode 12 is provided over the first AlGaN electron supply layer 3 via the insulating film 7, the semiconductor stacked structure is not limited thereto. For example, as illustrated in FIG. 8, the gate electrode 12 may be provided over the first AlGaN electron supply layer 3 without the insulating film 7 being provided over the bottom surface of the gate recess 9. That is, the gate electrode 12 may be provided so that the gate electrode 12 contacts the surface of the first AlGaN electron supply layer 3. The insulating film 7 is provided so that the insulating film 7 extends from the surface of the n-GaN protective layer 6 into the gate recess 9. The insulating film 7 may be provided so that the insulating film 7 covers the surface of the n-GaN protective layer 6 and does not extend into the gate recess 9. In this case, the side surface of the n-GaN protective layer 6, the side surface of the second n-AlGaN electron supply layer 5, and the side surface of the i-AlN electron supply layer 4 contact the side surface of the gate electrode 12.

All examples and conditional language recited herein are intended for pedagogical purposes to aid the reader in understanding the invention and the concepts contributed by the inventors to furthering the art, and are to be construed as being without limitation to such specifically recited examples and conditions, nor does the organization of such examples in the specification relate to a showing of the superiority and inferiority of the invention. Although the embodiment of the present invention have been described in detail, it should be understood that the various changes, substitutions, and alterations could be made hereto without departing from the spirit and scope of the invention.

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

What is claimed is:

1. A semiconductor device comprising:
a GaN electron transport layer provided over a substrate;
a first AlGaN electron supply layer provided over the GaN electron transport layer;
an AlN electron supply layer provided over the first AlGaN electron supply layer;
a second AlGaN electron supply layer provided over the AlN electron supply layer;
a gate recess provided in the second AlGaN electron supply layer and the AlN electron supply layer; and
a gate electrode provided over the gate recess.

2. The semiconductor device according to claim 1, further comprising:
a GaN protective layer provided over the second AlGaN electron supply layer;
wherein the gate recess is provided in the GaN protective layer, the second AlGaN electron supply layer, and the AlN electron supply layer.

3. The semiconductor device according to claim 1, wherein an Al content of the second AlGaN electron supply layer is lower than the Al content of the first AlGaN electron supply layer.

4. The semiconductor device according to claim 1, wherein an Al composition of the second AlGaN electron supply layer is 10% or less.

5. The semiconductor device according to claim 1, wherein a thickness of the AlN electron supply layer is 3 nm or less.

6. The semiconductor device according to claim 1, further comprising:
an insulating film that is provided over the gate recess,
wherein the gate electrode is provided over the first AlGaN electron supply layer via the insulating film.

7. The semiconductor device according to claim 2, further comprising:
an insulating film that extends from a surface of the GaN protective layer into the gate recess,
wherein the gate electrode is provided over the first AlGaN electron supply layer via the insulating film.

8. The semiconductor device according to claim 1, wherein the gate electrode is provided over the first AlGaN electron supply layer.

9. The semiconductor device according to claim 2, further comprising:
an insulating film that extends from a surface of the GaN protective layer into the gate recess,
wherein the gate electrode is provided over the first AlGaN electron supply layer.

10. A power supply apparatus comprising:
a high-voltage circuit;
a low-voltage circuit; and
a transformer that is provided between the high-voltage circuit and the low-voltage circuit;
the high-voltage circuit that includes a transistor, the transistor including:
a GaN electron transport layer provided over a substrate;
a first AlGaN electron supply layer provided over the GaN electron transport layer;
an AlN electron supply layer provided over the first AlGaN electron supply layer;
a second AlGaN electron supply layer provided over the AlN electron supply layer;
a gate recess provided in the second AlGaN electron supply layer and the AlN electron supply layer; and
a gate electrode provided over the gate recess.

11. A method of manufacturing a semiconductor device comprising:
forming a GaN electron transport layer over a substrate;
forming a first AlGaN electron supply layer over the GaN electron transport layer;
forming an AlN electron supply layer over the first AlGaN electron supply layer;
forming a second AlGaN electron supply layer over the AlN electron supply layer;
forming a gate recess in the second AlGaN electron supply layer and the AlN electron supply layer; and
forming a gate electrode over the gate recess.

12. The method of manufacturing a semiconductor device according to claim 11, wherein the gate recess is formed by selective dry etching to the second AlGaN electron supply layer.

13. The method of manufacturing a semiconductor device according to claim 12, wherein selective dry etching uses a chlorine-based gas and a fluorine-based gas, or a chlorine-based gas.

14. The method of manufacturing a semiconductor device according to claim 11, wherein an Al content of the second AlGaN electron supply layer is lower than the Al content of the first AlGaN electron supply layer.

15. The method of manufacturing a semiconductor device according to claim 11, wherein an Al composition of the second AlGaN electron supply layer is 10% or less.

16. The method of manufacturing a semiconductor device according to claim 11, wherein a thickness of the AlN electron supply layer is 3 nm or less.

17. The method of manufacturing a semiconductor device according to claim 11, wherein the gate recess is formed by selective wet etching to the AlN electron supply layer.

18. The method of manufacturing a semiconductor device according to claim 17, wherein selective wet etching uses phosphoric acid, or potassium hydroxide and tetra-methyl ammonium hydroxide as an etchant.

19. The method of manufacturing a semiconductor device according to claim 11, further comprising:
forming a GaN protective layer over the second AlGaN electron supply layer,
wherein the gate recess is formed in the GaN protective layer, the second AlGaN electron supply layer, and the AlN electron supply layer.

20. The method of manufacturing a semiconductor device according to claim 19, wherein the gate recess is formed by dry etching to the GaN protective layer using a chlorine-based gas.
